(19) United States
(12) Patent Application Publication
(10) Pub. No.: US 2021/0028389 A1
(43) Pub. Date: Jan. 28, 2021

(54) DISPLAY PANEL AND DISPLAY DEVICE

(71) Applicant: Wuhan China Star Optoelectronics Semiconductor Display Technology Co., LTD., Wuhan,Hubei Prov. (CN)

(72) Inventors: Wenzhi Zhang, Wuhan (CN); Rui Tang, Wuhan (CN)

(21) Appl. No.: 16/633,338

(22) PCT Filed: Oct. 9, 2019
(86) PCT No.: PCT/CN2019/110039

§ 371 Date: Jan. 23, 2020

(30) Foreign Application Priority Data
Jul. 23, 2019 (CN) 201910667199.6

(51) Int. Cl. H01L 51/52; H01L 27/32

(52) U.S. Cl. CPC H01L 51/5228; H01L 51/5206; H01L 27/3234

(57) ABSTRACT

The present invention provides a display panel and a display device. The display panel includes a displaying region and a non-displaying region. The displaying region includes a normal displaying sub-region and a light transmissive sub-region for a camera assembly to acquire light. A cathode layer is disposed on the display panel and includes in the normal displaying sub-region at least one main electrode sub-layer and at least one transparent auxiliary electrode sub-layer. The cathode layer includes in the light transmissive sub-region at least one transparent auxiliary electrode sub-layer to improve light transmittance of external light in the light transmissive sub-region.

### FIELD OF INVENTION

The present invention relates to a field of display technologies, especially to a display panel and a display device.

### BACKGROUND OF INVENTION

With increase of customers' requirement to a screen ratio, an under-screen camera type organic light emitting diode (OLED) display panel has become one of mainstream design solutions of OLED display panels. For an under-screen camera, it should be guaranteed that each layer in a light transmissive region right above the camera has a sufficient light transmittance. In a conventional top emission OLED display panel, under consideration of selectively using a translucent metal thin film such as an alloy of Mg and Ag for an electron injection potential barrier and a cathode layer. For the cathode of the metal thin film, reducing a thickness of the cathode can improve a light transmittance of the cathode in a certain degree by but results in sudden decrease of conductivity of the cathode such that displaying effect of the OLED display panel is influenced.

Therefore, the conventional technology has defects and urgently needs improvement.

### SUMMARY OF INVENTION

The present invention provides a display panel and a display device that are able to solve an issue that a light transmittance of a light transmissive region of an organic light emitting diode (OLED) display panel for an under-screen camera disposed thereon is low and affects performance of the camera and an issue that disposing the light transmissive region affects displaying effect of the OLED display panel.

To solve the above issue, the present invention provides technical solutions as follows.

The present invention provides a display panel, comprising:

a substrate comprising a displaying region and a non-displaying region, the displaying region comprising a normal displaying sub-region and a light transmissive sub-region configured to acquire light for a camera assembly;

an anode layer disposed on the substrate;

a light emitting layer disposed on the anode layer; and

a cathode layer disposed on the light emitting layer, the cathode layer comprising at least one main electrode sub-layer and at least one transparent auxiliary electrode sub-layer stacked on one another in the normal displaying sub-region, and the cathode layer comprising at least one the transparent auxiliary electrode sub-layer in the light transmissive sub-region.

In the display panel of the present invention, in the normal displaying sub-region, the main electrode sub-layer contacts the light emitting layer, the transparent auxiliary electrode sub-layer is located on the main electrode sub-layer, wherein the main electrode sub-layer is broken on a boundary of the light transmissive sub-region, the transparent auxiliary electrode sub-layer contacts the light emitting layer in the light transmissive sub-region.

In the display panel of the present invention, the anode layer, the light emitting layer and the cathode layer form pixel units distributed at intervals, wherein a distribution density of the pixel units in the normal displaying sub-region is greater than or equal to a distribution density of the pixel units in the light transmissive sub-region.

In the display panel of the present invention, after the transparent auxiliary electrode sub-layer is patterned, the transparent auxiliary electrode sub-layer forms an opening region in a gap between adjacent two of the pixel units in the light transmissive sub-region, and a hole is defined in a position of the display panel corresponding to the opening region.

In the display panel of the present invention, after the transparent auxiliary electrode sub-layer is patterned, the transparent auxiliary electrode sub-layer corresponding to the light transmissive sub-region forms electrode units corresponding to the pixel units and electrode leads each of which is located between adjacent two of the holes and is electrically connected to adjacent two of the electrode units, wherein the electrode units, the electrode leads, and the transparent auxiliary electrode sub-layer out of the light transmissive sub-region are formed integrally.

In the display panel of the present invention, material of the transparent auxiliary electrode sub-layer comprises one or more of graphene, indium tin oxide, and zinc oxide doped with aluminum, material of the main electrode sub-layer is a translucent metal material.

In the display panel of the present invention, an orthographic projection range of the transparent auxiliary electrode sub-layer on the display panel is greater than an orthographic projection range of the light transmissive sub-region on the display panel, and is less than or equal to an orthographic projection range of the main electrode sub-layer on the display panel.

To solve the above technical issue, the present invention further provides a display device, comprising the display panel as above and a camera assembly;

wherein the camera assembly corresponds to the light transmissive sub-region and is disposed on a rear of the display panel, the camera assembly is configured to photograph an object on a side of the display panel away from the camera assembly.

In the display device of the present invention, the camera assembly comprises a light sensitive unit, the light sensitive unit is configured to sense light passing from an external through the light transmissive sub-region of the display panel and emitted to the light sensitive unit, and a range of the light transmissive sub-region is a light sensing range of the light sensitive unit.

To solve the above issue, the present invention also provides a display panel, comprising:

a substrate comprising a displaying region and a non-displaying region, the displaying region comprising a normal displaying sub-region and a light transmissive sub-region configured to acquire light for a camera assembly;

an anode layer disposed on the substrate;

a light emitting layer disposed on the anode layer;

a cathode layer disposed on the light emitting layer, the cathode layer comprising at least one main electrode sub-layer and at least one transparent auxiliary electrode sub-layer stacked on one another in the normal displaying sub-region, and the cathode layer comprising at least one the transparent auxiliary electrode sub-layer in the light transmissive sub-region; and

a film layer thickness of a portion of the transparent auxiliary electrode sub-layer corresponding to the light transmissive sub-region being greater than or equal to a film layer thickness of a portion of the transparent auxiliary electrode sub-layer corresponding to the normal displaying sub-region.

In the display panel of the present invention, in the normal displaying sub-region, the main electrode sub-layer contacts the light emitting layer, the transparent auxiliary electrode sub-layer is located on the main electrode sub-layer, wherein the main electrode sub-layer is broken on a boundary of the light transmissive sub-region, the transparent auxiliary electrode sub-layer contacts the light emitting layer in the light transmissive sub-region.

In the display panel of the present invention, the anode layer, the light emitting layer and the cathode layer form pixel units distributed at intervals, wherein a distribution density of the pixel units in the normal displaying sub-region is greater than or equal to a distribution density of the pixel units in the light transmissive sub-region.

In the display panel of the present invention, after the transparent auxiliary electrode sub-layer is patterned, the transparent auxiliary electrode sub-layer forms an opening region in a gap between adjacent two of the pixel units in the light transmissive sub-region, and a hole is defined in a position of the display panel corresponding to the opening region.

In the display panel of the present invention, after the transparent auxiliary electrode sub-layer is patterned, the transparent auxiliary electrode sub-layer corresponding to the light transmissive sub-region forms electrode units corresponding to the pixel units and electrode leads each of which is located between adjacent two of the holes and is electrically connected to adjacent two of the electrode units, wherein the electrode units, the electrode leads, and the transparent auxiliary electrode sub-layer out of the light transmissive sub-region are formed integrally.

In the display panel of the present invention, material of the transparent auxiliary electrode sub-layer comprises one or more of graphene, indium tin oxide, and zinc oxide doped with aluminum, material of the main electrode sub-layer is a translucent metal material.

In the display panel of the present invention, an orthographic projection range of the transparent auxiliary electrode sub-layer on the display panel is greater than an orthographic projection range of the light transmissive sub-region on the display panel, and is less than or equal to an orthographic projection range of the main electrode sub-layer on the display panel.

Advantages of the present invention are as follows. Compared to a conventional under-screen camera display device, the display panel and the display device provided by the present invention employ a light sensitive region (light transmissive sub-region) of an under-screen camera as a boundary, portions of a cathode layer out of the light transmissive sub-region of the display panel are constituted commonly by at least one main electrode sub-layer and at least one transparent auxiliary electrode sub-layer, and portions of the cathode layer out in the light transmissive sub-region are only constituted by at least one transparent auxiliary electrode sub-layer independently. By using such design, not only a light transmittance of the light transmissive sub-region for external light is improved, but also displaying capability of the light transmissive sub-region is guaranteed such that photographing capability and of the under-screen camera and displaying effect of the display panel become better.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic structural view of a display panel provided by an embodiment of the present invention;

FIG. 2 is a schematic cross-sectional view along line E-E′ in FIG. 1;

FIG. 3 is a schematic plane view of a light transmissive sub-region of another display panel provided by an embodiment of the present invention; and

FIG. 4 is a schematic structural view of a display device provided by an embodiment of the present invention.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

The present invention aims at the issues that in a conventional under-screen camera display device a light transmittance of a light transmissive region of an under-screen camera of a display panel is lower to influence performance of the camera, and disposing the light transmissive region affects displaying effect of an OLED display panel. The present embodiment can solve the defects.

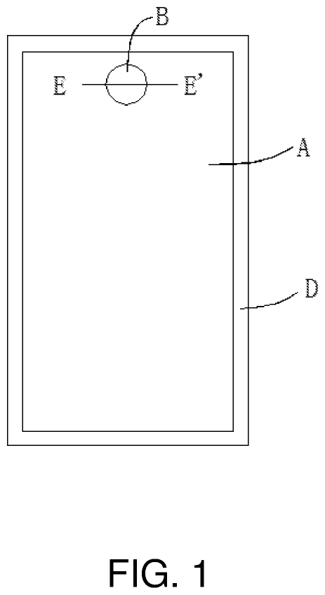

With reference to FIG. 1, FIG. 1 is a schematic structural view of a display panel provided by an embodiment of the present invention. To increase a screen ratio, the display panel of the present invention is an under-screen camera type display panel and comprises: a displaying region and a non-displaying region D. The displaying region comprises a normal displaying sub-region A, and a light transmissive sub-region B for a camera assembly to acquire light. The under-screen camera assembly is disposed on a position of a rear of the display panel corresponding to the light transmissive sub-region B. The camera assembly is configured to photograph an object on a side of the display panel away from the camera assembly. In other words, external light is emitted toward the camera assembly through the light transmissive sub-region B and achieves normal use of the camera assembly.

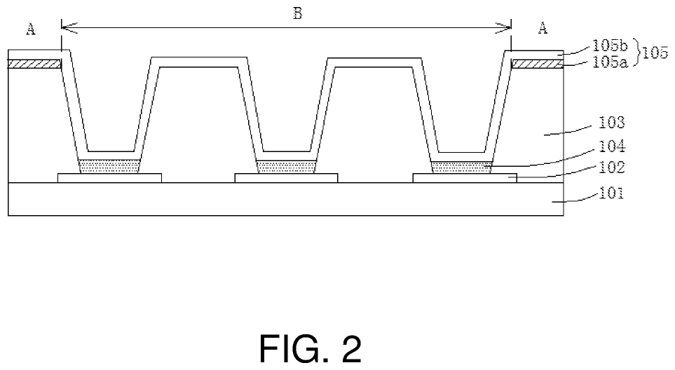

With reference to FIG. 2, FIG. 2 is a schematic cross-sectional view along line E-E′ in FIG. 1. The display panel comprises a substrate 101, and the substrate 101 can be an array substrate disposed with a thin film transistor (not shown in the figures). An anode layer 102 is disposed on the substrate 101, the anode layer 102 comprises an anode arranged in an array, a pixel definition layer 103 is disposed in a gap between adjacent two of the anodes, and the light emitting layer 104 is disposed on the anode layer 102. A cathode layer 105 is disposed on the light emitting layer 104. The anode layer 102, the light emitting layer 104, and the cathode layer 105 stacked on one another form a plurality of pixel units.

a distribution density of the pixel units in the normal displaying sub-region A out of the light transmissive sub-region B is greater than or equal to a distribution density of the light transmissive sub-region B.

The display panel can further comprise a regular film layer such as a thin film encapsulation layer (not shown in the figures) and no limitation is thereto.

The cathode layer 105 comprises at least one main electrode sub-layer 105a and at least one transparent auxiliary electrode sub-layer 105b that are stacked on each other. The cathode layer 105 of the display panel corresponding to the normal displaying sub-region A comprises at least one the main electrode sub-layer 105a and at least one the transparent auxiliary electrode sub-layer 105b. The cathode layer 105 of the display panel corresponding to the light transmissive sub-region B is at least one the transparent auxiliary electrode sub-layer 105b.

A shape of the light transmissive sub-region B comprises but is not limited to square, diamond, circle, teardrop, and oval, and has no limit to a position of the light transmissive sub-region B.

With reference to FIG. 2, in the normal displaying sub-region A out of the light transmissive sub-region B, the main electrode sub-layer 105a contacts the light emitting layer 104, and the transparent auxiliary electrode sub-layer 105b is located above the main electrode sub-layer 105a. the main electrode sub-layer 105a is broken on a boundary of the light transmissive sub-region B. in other words, the main electrode sub-layer 105a corresponding the light transmissive sub-region B is removed, and the transparent auxiliary electrode sub-layer 105b contacts the light emitting layer 104 in the light transmissive sub-region B. The transparent auxiliary electrode sub-layer 105b is a layer of a continuous thin film.

To ensure an excellent electron injection potential barrier, material of the main electrode sub-layer 105a is a translucent metal material comprising but not limited to one of Al, Mg, Ca, and an alloy including at least one thereof. The main electrode sub-layer 105a can comprise a single layer or multiple layers, and a thickness thereof is preferably in a range of 0.1 nm-20 nm. The main electrode sub-layer 105a covers a portion in the normal displaying sub-region A and out of the light transmissive sub-region B. Material of the transparent auxiliary electrode sub-layer 105b is a translucent material and comprises but is not limited to one or more of graphene, indium tin oxide, and zinc oxide doped with aluminum.

Preferably, material of the transparent auxiliary electrode sub-layer 105b is graphene. Graphene has a higher carrier mobility and superior electrical conductivity, and also has excellent optical characteristics. In a wide range of wave length, an absorption rate of graphene is 2.3% so graphene looks almost transparent. In a thickness range of several layers of graphene, an absorption rate is increased by 2.3% for a thickness of each additional layer, and optical characteristics thereof vary according to variation of the thickness of graphene.

An orthographic projection range of the transparent auxiliary electrode sub-layer 105b on the display panel is greater than an orthographic projection range of the light transmissive sub-region B on the display panel, and is less than or equal to an orthographic projection range of the main electrode sub-layer 105a on the display panel.

In the present embodiment, because portions of the cathode layer 105 of the display panel out of the light transmissive sub-region B are commonly constituted by at least one the main electrode sub-layer 105a and the at least one the transparent auxiliary electrode sub-layer 105b, portions of the cathode layer 105 in the light transmissive sub-region B are only constituted by the at least one the transparent auxiliary electrode sub-layer 105b independently. Therefore, by assistance of the transparent auxiliary electrode sub-layer 105b, in one aspect, it is ensured that light emitting performance in the light transmissive sub-region B of the display panel is still preserved, in other words, the transparent auxiliary electrode sub-layer 105b in the light transmissive sub-region B serves as a cathode cooperating with the light emitting layer 104 and the anode layer 102 to form the pixel units being able to emit light. In another aspect, the high light transmittance of the transparent auxiliary electrode sub-layer 105b provides feasibility for external light passing through the light transmissive sub-region B and entering the light sensitive unit of the under-screen camera assembly.

In an embodiment, a film layer thickness of a portion of the transparent auxiliary electrode sub-layer 105b corresponding to the light transmissive sub-region B is greater than or equal to a film layer thickness of a portion of the transparent auxiliary electrode sub-layer 105b corresponding to the normal displaying sub-region A out of the light transmissive sub-region B. A specific film layer thickness has no limitation as long as an excellent conductivity thereof in the light transmissive sub-region B is ensured.

In an embodiment, the film layer thickness of the portion of the transparent auxiliary electrode sub-layer 105b corresponding to the light transmissive sub-region B is equal to the film layer thickness of the cathode layer 105 in the normal displaying sub-region A out of the light transmissive sub-region B such that the film layer thickness of the cathode layer 105 is kept uniform in each portion of the display panel to facilitate manufacturing subsequent film layers and to guarantee the excellent conductivity of each portion of the cathode layer 105.

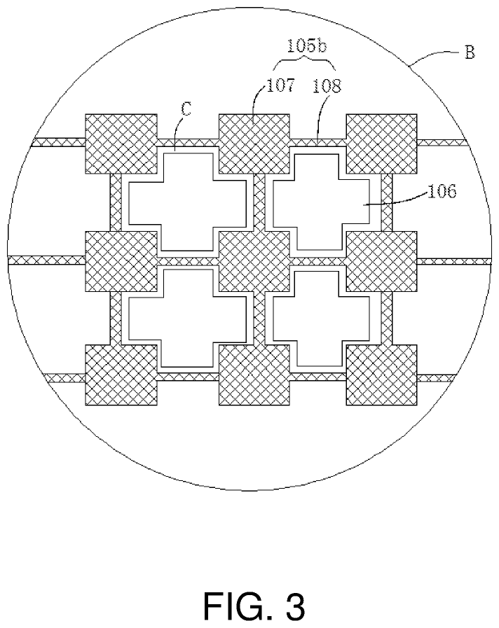

With reference to FIG. 3, in another embodiment, the distribution density of the pixel units in the normal displaying sub-region A is greater than the distribution density of the pixel units in the light transmissive sub-region B. In the present embodiment, the transparent auxiliary electrode sub-layer 105b corresponding to the light transmissive sub-region B is patterned, and after patterned the transparent auxiliary electrode sub-layer 105b forms electrode units 107 corresponding to the pixel units and forms opening regions C in gaps each of which is between adjacent two of the pixel units in the light transmissive sub-region B and the opening regions C are disposed at intervals. A hole 106 is defined in a position of the display panel corresponding to each of the opening regions C. Under a condition of the hole 106 having no influence to displaying of the pixel units in the light transmissive sub-region B, the hole 106 can be defined through a organic film layer and an inorganic film layer on the display panel, The organic film layer comprises but is not limited to the pixel definition layer, and the inorganic film layer comprises but is not limited to a passivation layer, an interlayer dielectric layer, and a gate insulation layer.

During a patterning process of the transparent auxiliary electrode sub-layer 105b, electrode leads 108 are formed and each electrode lead 108 is located between adjacent two of the holes 106 and is electrically connected to adjacent two of the electrode units 107. The electrode units 107, the electrode leads 108, and the transparent auxiliary electrode sub-layer 105b out of the light transmissive sub-region B are formed integrally.

In another embodiment, the hole 106 can be a blind hole, in other words, there is no need to pattern the transparent auxiliary electrode sub-layer 105b of the light transmissive sub-region B, but it is no limited thereto.

A shape of the opening region C or the hole 106 is not limited. Under a condition of no influence to normal displaying, the opening region C or the hole 106 can be as larger as possible.

By such design, not only a displaying function in the light transmissive sub-region B is retained, but also consumption of external light passing through the light transmissive sub-region B is decreased by reducing the distribution density of the pixel units in the light transmissive sub-region B and disposing the hole 106 in adjacent two of the pixel units such that the light transmittance of the external light is further enhanced.

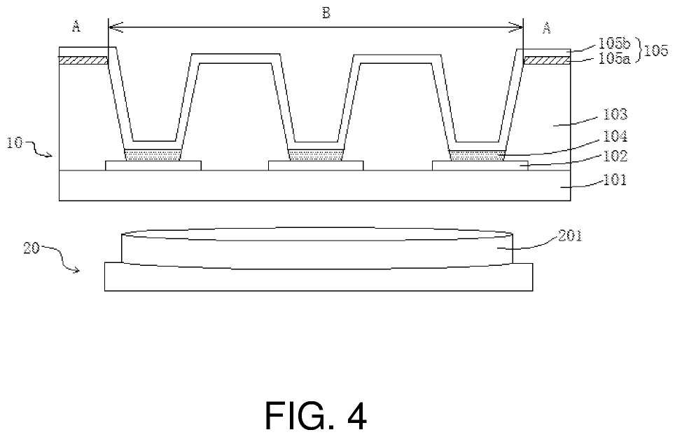

The present invention also provides a display device, as shown in FIG. 4, the display device comprises the display panel 10 as above and a camera assembly 20. The camera assembly 20 corresponds to the light transmissive sub-region B and is disposed on a rear of the display panel 10. The camera assembly 20 is is configured to photograph an object on a side of the display panel 10 away from the camera assembly 20. The camera assembly 20 comprises a light sensitive unit 201, the light sensitive unit 201 is configured to sense light passing from an external through the light transmissive sub-region B of the display panel 10 and emitted to the light sensitive unit 201 such that normal photographing of the camera assembly 20 is achieved. To avoid influence to photographing performance of the camera assembly 20, a range of the light transmissive sub-region B is a light sensing range of the light sensitive unit 201.

As described above, the display panel and the display device provided by the present invention employ a light sensitive region (light transmissive sub-region) of an under-screen camera as a boundary, portions of a cathode layer out of the light transmissive sub-region of the display panel are constituted commonly by at least one main electrode sub-layer and at least one transparent auxiliary electrode sub-layer, and portions of the cathode layer out in the light transmissive sub-region are only constituted by at least one transparent auxiliary electrode sub-layer independently. By using such design, not only a light transmittance of the light transmissive sub-region for external light is improved, but also displaying capability of the light transmissive sub-region is guaranteed such that photographing capability and of the under-screen camera and displaying effect of the display panel become better.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. A display panel, comprising:
a substrate comprising a displaying region and a non-displaying region, the displaying region comprising a normal displaying sub-region and a light transmissive sub-region configured to acquire light for a camera assembly;
an anode layer disposed on the substrate;
a light emitting layer disposed on the anode layer; and
a cathode layer disposed on the light emitting layer, the cathode layer comprising at least one main electrode sub-layer and at least one transparent auxiliary electrode sub-layer stacked on one another in the normal displaying sub-region, and the cathode layer comprising at least one the transparent auxiliary electrode sub-layer in the light transmissive sub-region.

2. The display panel as claimed in claim 1, wherein in the normal displaying sub-region, the main electrode sub-layer contacts the light emitting layer, the transparent auxiliary electrode sub-layer is located on the main electrode sub-layer, wherein the main electrode sub-layer is broken on a boundary of the light transmissive sub-region, the transparent auxiliary electrode sub-layer contacts the light emitting layer in the light transmissive sub-region.

3. The display panel as claimed in claim 2, wherein the anode layer, the light emitting layer and the cathode layer form pixel units distributed at intervals, wherein a distribution density of the pixel units in the normal displaying sub-region is greater than or equal to a distribution density of the pixel units in the light transmissive sub-region.

4. The display panel as claimed in claim 3, wherein after the transparent auxiliary electrode sub-layer is patterned, the transparent auxiliary electrode sub-layer forms an opening region in a gap between adjacent two of the pixel units in the light transmissive sub-region, and a hole is defined in a position of the display panel corresponding to the opening region.

5. The display panel as claimed in claim 4, wherein after the transparent auxiliary electrode sub-layer is patterned, the transparent auxiliary electrode sub-layer corresponding to the light transmissive sub-region forms electrode units corresponding to the pixel units and electrode leads each of which is located between adjacent two of the holes and is electrically connected to adjacent two of the electrode units, wherein the electrode units, the electrode leads, and the transparent auxiliary electrode sub-layer out of the light transmissive sub-region are formed integrally.

6. The display panel as claimed in claim 1, wherein material of the transparent auxiliary electrode sub-layer comprises one or more of graphene, indium tin oxide, and zinc oxide doped with aluminum, material of the main electrode sub-layer is a translucent metal material.

7. The display panel as claimed in claim 1, wherein an orthographic projection range of the transparent auxiliary electrode sub-layer on the display panel is greater than an orthographic projection range of the light transmissive sub-region on the display panel, and is less than or equal to an orthographic projection range of the main electrode sub-layer on the display panel.

8. A display device, comprising: the display panel as claimed in claim 1 and a camera assembly;
wherein the camera assembly corresponds to the light transmissive sub-region and is disposed on a rear of the display panel, the camera assembly is configured to photograph an object on a side of the display panel away from the camera assembly.

9. The display device as claimed in claim 8, wherein the camera assembly comprises a light sensitive unit, the light sensitive unit is configured to sense light passing from an external through the light transmissive sub-region of the display panel and emitted to the light sensitive unit, and a range of the light transmissive sub-region is a light sensing range of the light sensitive unit.

10. A display panel, comprising:
a substrate comprising a displaying region and a non-displaying region, the displaying region comprising a normal displaying sub-region and a light transmissive sub-region configured to acquire light for a camera assembly;
an anode layer disposed on the substrate;
a light emitting layer disposed on the anode layer;
a cathode layer disposed on the light emitting layer, the cathode layer comprising at least one main electrode sub-layer and at least one transparent auxiliary electrode sub-layer stacked on one another in the normal displaying sub-region, and the cathode layer comprising at least one the transparent auxiliary electrode sub-layer in the light transmissive sub-region; and
a film layer thickness of a portion of the transparent auxiliary electrode sub-layer corresponding to the light transmissive sub-region being greater than or equal to a film layer thickness of a portion of the transparent auxiliary electrode sub-layer corresponding to the normal displaying sub-region.

11. The display panel as claimed in claim 10, wherein in the normal displaying sub-region, the main electrode sub-layer contacts the light emitting layer, the transparent auxiliary electrode sub-layer is located on the main electrode sub-layer, wherein the main electrode sub-layer is broken on a boundary of the light transmissive sub-region, the transparent auxiliary electrode sub-layer contacts the light emitting layer in the light transmissive sub-region.

12. The display panel as claimed in claim 11, wherein the anode layer, the light emitting layer and the cathode layer form pixel units distributed at intervals, wherein a distribution density of the pixel units in the normal displaying sub-region is greater than or equal to a distribution density of the pixel units in the light transmissive sub-region.

13. The display panel as claimed in claim 12, wherein after the transparent auxiliary electrode sub-layer is patterned, the transparent auxiliary electrode sub-layer forms an opening region in a gap between adjacent two of the pixel units in the light transmissive sub-region, and a hole is defined in a position of the display panel corresponding to the opening region.

14. The display panel as claimed in claim 13, wherein after the transparent auxiliary electrode sub-layer is patterned, the transparent auxiliary electrode sub-layer corresponding to the light transmissive sub-region forms electrode units corresponding to the pixel units and electrode leads each of which is located between adjacent two of the holes and is electrically connected to adjacent two of the electrode units, wherein the electrode units, the electrode leads, and the transparent auxiliary electrode sub-layer out of the light transmissive sub-region are formed integrally.

15. The display panel as claimed in claim 10, wherein material of the transparent auxiliary electrode sub-layer comprises one or more of graphene, indium tin oxide, and zinc oxide doped with aluminum, material of the main electrode sub-layer is a translucent metal material.

16. The display panel as claimed in claim 10, wherein an orthographic projection range of the transparent auxiliary electrode sub-layer on the display panel is greater than an orthographic projection range of the light transmissive sub-region on the display panel, and is less than or equal to an orthographic projection range of the main electrode sub-layer on the display panel.
